(19) United States
(12) Patent Application Publication
(10) Pub. No.: US 2009/0108262 A1
(43) Pub. Date: Apr. 30, 2009

(54) DISPLAY DEVICE

(75) Inventor: Kenichi MINOWA, Koshi-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Tokyo (JP)

(21) Appl. No.: 12/246,700

(22) Filed: Oct. 7, 2008

(30) Foreign Application Priority Data
Oct. 31, 2007 (JP) 2007-283339

(51) Int. Cl. H01L 29/04

(52) U.S. Cl. 257/59; 257/E29.003

(57) ABSTRACT

A display device includes an insulative array-substrate provided with display areas, composed of a plurality of pixels, formed thereon; an opposite substrate disposed opposite the array substrate; opposite electrodes, each individually corresponding to the pixels, formed on the surface opposite to the array substrate, of the opposite substrate; a black matrix formed between the opposite electrodes; and a projection portion formed on each of the opposite electrodes, for electrically connecting the black matrix with each opposite electrode.

### FIELD OF THE INVENTION

The present invention relates to a display device, which uses, for example, a liquid crystal, that prevents its pixels from becoming defective when a foreign matter is mixed into the liquid crystal layer, and that can be repaired even when a pixel thereof becomes defective.

### BACKGROUND OF THE INVENTION

A conventional liquid crystal display device has a pair of substrates facing each other, and the gap between the substrates is held constant by spacers and filled with liquid crystal. One of the substrates is an active-matrix insulative substrate (hereinafter, referred to as “array substrate”) provided with a plurality of pixels formed thereon, each of which has a switching element such as a thin film transistor. The other is an insulative substrate (hereinafter, referred to as “opposite substrate”) provided with color filters formed thereon. Transparent conductive films each are formed on the substrate surfaces facing each other, and drive of the liquid crystal is controlled by voltage to be applied across the conductive films. For the transparent conductive films, indium tin oxide (ITO) or indium zinc oxide (IZO) is generally used. In general, transparent conductive films on the array substrate are formed not on wirings but on areas where pixel electrodes of the active matrix are to be formed. On the other hand, an opposite electrode on the opposite substrate, which is usually made of a transparent conductive film, is formed on the almost entire surface of the substrate. While the spacers, made of an insulative material, may in some cases touch the transparent conductive films, when a conductive foreign matter is mixed in between a transparent conductive film of the array substrate and that of the opposite substrate, current is short-circuited therebetween, so that voltage cannot be maintained between the transparent conductive films, causing the pixel to be a point defect. Occurrence of a point defect in a liquid-crystal display device is a factor that reduces its quality and production yield.

As a conventional technology of repairing such a point defect, the following technology has been disclosed in Japanese Patent Application Publication: H09-15619. An opposite electrode, made of a conductive film, on an opposite substrate is separately formed into a plurality of small electrodes that are connected with each other through narrow-width connecting portions of the conductive film. Accordingly, even when a short circuit occurs between a signal line on the array substrate and one of the small opposite electrodes, by severing the narrow-width conductive-film connecting portions connected to the short-circuited small electrode, for example, by irradiating a laser beam on the connecting portions, the signal line is not affected by electric potential of the short-circuited opposite electrode, whereby a linear defect is improved into a less conspicuous point defect.

In the conventional technology disclosed in the patent document, however, adjacent small opposite electrodes are connected with each other by a narrow-width conductive-film connecting portion, and if a conductive foreign matter exists on a narrow-width conductive-film connecting portion, severance of the connecting portion will be impossible. That is, it is difficult to isolate the defective portion, for example, by irradiating thereon a laser beam. Moreover, in the conventional technology, since such a connecting portion is formed on every side of a pixel, when a conductive foreign matter exists on any one of the connecting portions, there has been a problem in that the defect is difficult to repair as described above.

### SUMMARY OF THE INVENTION

The present invention is made in light of such problem, and an object of the invention is to obtain a display device whose defective pixel produced due to a foreign matter during the manufacturing process can be repaired.

A display device of the invention comprises an insulative array-substrate provided with display areas, composed of a plurality of pixels, formed thereon; an opposite substrate disposed opposite the array substrate; opposite electrodes, each individually corresponding to the pixels, formed on the surface opposite to the array substrate, of the opposite substrate; a black matrix formed between the opposite electrodes; and a projection portion formed on each of the opposite electrodes, for electrically connecting the black matrix with each opposite electrode.

According to the invention, it is possible to obtain a display device whose defective pixel produced due to a foreign matter during the manufacturing process can be repaired.

### BRIEF DESCRIPTION OF THE DRAWINGS

FIG. 1 is a plane view illustrating an opposite substrate of a display device according to Embodiment of the present invention;

FIG. 2 is a cross-sectional view taken along the A-A line after the opposite substrate in FIG. 1 and an array substrate have been bonded together; and

FIG. 3 is a plane view illustrating nearly one pixel of the display device at ingress of a foreign matter, in Embodiment of the invention.

### DETAILED DESCRIPTION OF THE PREFERRED EMBODIMENT

### Embodiment

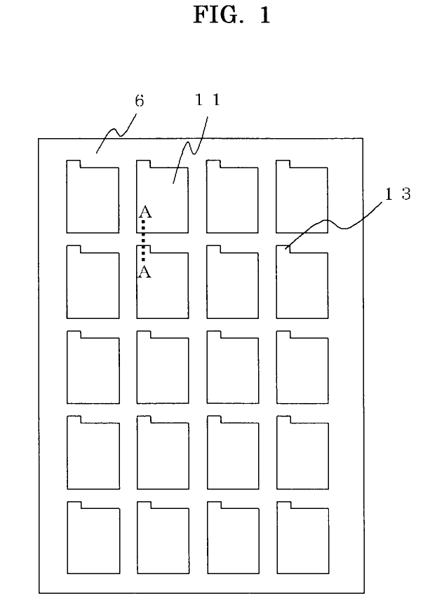

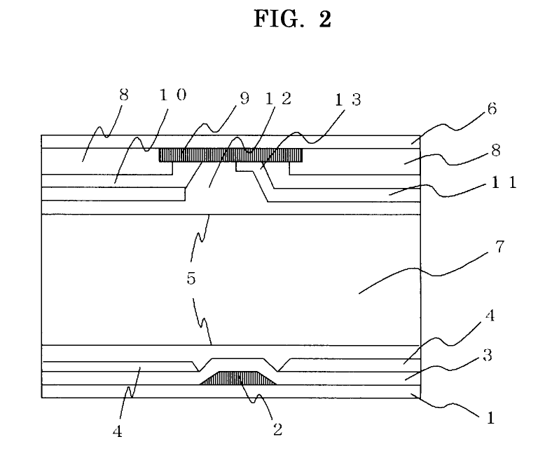

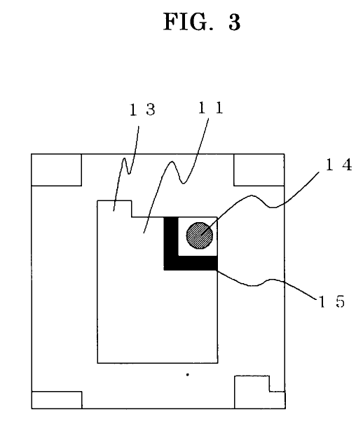

Embodiment of the present invention will be described with reference to FIG. 1 through FIG. 3. FIG. 1 is a plane view illustrating an opposite substrate 6 of a display device according to Embodiment of the invention; FIG. 2 is a cross-sectional view taken along the A-A line after the opposite substrate 6 in FIG. 1 and an array substrate 1 of the display device have been bonded together; and FIG. 3 is a plane view illustrating nearly one pixel of the display device at ingress of a foreign matter, in Embodiment of the invention.

In FIGS. 1 and 2, on the array substrate 1, formed are wirings 2 such as scan lines for scanning pixels composing display areas and video signal lines that are connected with the pixels, and formed is an insulation film 3 made of an oxide film, a nitride film, or the like so as to cover the wirings 2. A transparent conductive film is deposited on the insulation film 3 and further formed into pixel electrodes 4, and then, an alignment film 5 is formed thereon. The opposite substrate 6 is disposed opposite the array substrate 1, with a liquid crystal layer 7 being interposed therebetween. The gap between both substrates is held to a predetermined distance by spacers (not shown in the figures), which are made of beads dispersed therebetween, columns formed beforehand on either one of the substrates, or the like. On the surface of the opposite substrate 6, facing the array substrate 1, color filters 8 composed of red, green, and blue ones are formed, and each color filter makes up one pixel. A black matrix 9 made of a lightproof metal film is formed between adjacent color filters to prevent leakage of unnecessary light. An overcoat layer 10 made of an organic film or the like is further formed on the color filters 8 and the black matrix 9. This overcoat layer 10 can be omitted if unnecessary. Opposite electrodes 11 made of a transparent conductive film or the like are then formed on the overcoat layer 10. The opposite electrodes 11 are formed on almost the entire surface above the opposite substrate first, and then individually patterned into a shape corresponding to each of the pixels formed on the array substrate. After that, an alignment film 5 is further formed on the opposite electrodes.

The opposite electrodes 11 individually formed on a pixel basis each have a projection portion 13 on one side of each opposite electrode, as shown in FIG. 1. The projection portion 13 is electrically connected with the black matrix 9 by removing part of the overcoat layer 10 having been formed thereon to form an opening 12, as shown in FIG. 2, that is, the opposite electrodes on the opposite substrate and the black matrix are electrically connected with each other. Employing such a structure, when a foreign matter is mixed in between opposite electrodes adjacent to each other, except for the portion shown by the A-A line in FIG. 2, since there is no conductive film on the opposite substrate side, a defect can be prevented from occurring that is caused by a short circuit between an opposite electrode, and a wiring or the like on the array substrate. In many cases, none of the pixel electrodes 4 are ordinarily formed immediately above the wirings 2 formed on the array substrate 1 as shown in FIG. 2. Accordingly, even if the pixel electrodes 4 are formed on the wirings 2, since no conductive film exists between opposite electrodes adjacent to each other, as mentioned above, it is possible to prevent a short circuit between the array substrate and opposite substrate.

FIG. 3 is a plane view illustrating almost one pixel of the display device according to Embodiment when a conductive foreign matter is mixed in on an opposite electrode thereof. A method of repairing a defect occurring when a conductive foreign matter 14 is mixed in on one of the opposite electrodes 11, is explained with reference to FIG. 3. When, as shown in FIG. 3, the conductive foreign matter 14 is mixed in one of the pixel regions where the opposite electrodes 11 are formed, two sides of such a rectangle, inside the region of the opposite electrodes 11, that surrounds the conductive foreign matter 14 and whose other sides are portions of two opposite-electrode sides adjacent to the foreign matter 14, are irradiated by a laser beam. By thus doing, the portion where a defect occurs can be isolated from the other portions, which allows a short circuit between the array substrate and the opposite substrate to be eliminated and the defect to be repaired. For the irradiation, it is preferable to use an yttrium-aluminum-garnet (YAG) laser or an excimer laser, and its beam wavelength is preferable to be 0.1 to 1.06 μm. Moreover, irradiation intensity of the laser beam is preferable in a range from 1×10² to 1×10⁴ J/m².

Employing such a structure described above, when the conductive foreign matter 14 is mixed into a portion on the opposite electrodes 11 other than that on the projection portion 13 that is formed on a pixel basis, the periphery of the portion around the conductive foreign matter is irradiated by a laser beam to isolate the portion from the other portions. Thereby, it is possible to eliminate a short circuit, caused by the conductive foreign matter, between the array substrate and the opposite substrate. In the embodiment, in particular, since an unrepairable portion is limited to only one side of each pixel, repairable portions are more expanded and a defect can be repaired.

In Embodiment, the description is made of the case in which the projection portion is formed on only one side of each pixel. On the other hand, for the reason of improving stability of electric potential of the opposite electrode and for other reasons, two such projection portions may be formed on two sides adjacent or opposite to each other to be connected with a black matrix, or three such projection portions may be formed on three sides.

Up to this point, the description has been made, as an example of Embodiment, on a display device using a liquid crystal. The present invention however is not limited to that, and can be applied to all display devices that have opposite electrodes formed on an opposite substrate opposite to an array substrate and have wirings thereon.

What is claimed is:

1. A display device comprising:
an insulative array-substrate provided with display areas, composed of a plurality of pixels, formed thereon;
an opposite substrate disposed opposite the array substrate;
opposite electrodes, each individually corresponding to the pixels, formed on the surface opposite to the array substrate, of the opposite substrate;
a black matrix formed between the opposite electrodes; and
a projection portion formed on each of the opposite electrodes, for electrically connecting the black matrix with each opposite electrode.

2. The display device of claim 1, wherein the projection portion is formed on only one portion of each opposite electrode.
